(19) United States
(12) Patent Application Publication
(10) Pub. No.: US 2018/0323387 A1
(43) Pub. Date: Nov. 8, 2018

(54) Unipolar N- or P-Type Carbon Nanotube Transistors and Methods of Manufacture Thereof

(71) Applicant: Atom Nanoelectronics, Inc., Los Angeles, CA (US)

(72) Inventor: Huaping Li, Los Angeles, CA (US)

(21) Appl. No.: 15/971,987

(22) Filed: May 4, 2018

Related U.S. Application Data
(60) Provisional application No. 62/501,611, filed on May 4, 2017.

(51) Int. Cl. H01L 51/05; H01L 51/00; H01L 51/10

(52) U.S. Cl. CPC H01L 51/0516; H01L 51/0048; B82Y 40/00; H01L 51/0545; H01L 51/105; H01L 51/0541

(57) ABSTRACT

Devices, materials and methods for producing and integrating carbon nanotubes (CNT) into TFTs to form unipolar CNT TFTs are provided. CNT TFTs comprise doped layers between the CNT active layer and the source/drain electrodes capable of providing a carrier-trapping function such that unwanted carrier charge injection is suppressed between the electrodes allowing for the unipolar operation of CNT TFTs. Methods and apparatus for forming unipolar N- or P-type SWCNT TFTs are also provided.

### CROSS-REFERENCE TO RELATED APPLICATIONS

This application claims priority to U.S. Provisional Patent Application No. 62/501,611, filed May 4, 2017, the disclosure of which is incorporated herein by reference.

### FIELD OF THE INVENTION

The present disclosure relates to carbon nanotube transistors and methods of their manufacture, and more particularly to unipolar N- or P-type carbon nanotube transistors.

### BACKGROUND OF THE INVENTION

Thin film transistors (TFTs) and field emission transistors (FETs) may be employed in a plurality of different applications. In one instance, TFTs are employed in active matrix displays for the purpose of pixel switching. However, there are a variety of TFT structures described in the prior art, including two top gate designs and two bottom gate designs. Regardless of the specific design the TFTs function in a same manner. Each structure includes a source, a drain, and a gate, and all structures are formed on a substrate and include suitable insulation layers.

The use of nanotubes as active layers in such TFTs and FETs are known and demonstrate excellent electronic properties, which make them potentially valuable for a wide range of electronic applications. However, such nanotube field effect transistors typically display ambipolar electronic characteristics, which make them undesirable for use in many applications. A number of strategies have been employed to address this ambipolar tendency in such nanotube devices. For example, attempts have been made to address the switching behavior of carbon nanotube field-effect transistors by decreasing the gate oxide thickness. However, this results in even more pronounced ambipolar transistor characteristics and higher off-currents, both of which are undesirable. (See, e.g., Yu-Ming Lin, et al., Nano Letters 2004, Vol. 4, No. 5, pp. 947-950, the disclosure of which is incorporated herein by reference.) Improvements to the switching behavior of carbon nanotube FETs has also been made using dielectric materials with relatively high dielectric constant K. However, the Schottky barrier contacts formed at the interface between the nanotubes and the metal causes poor scaling behavior.

A number of techniques have been described to convert an am bipolar carbon nanotube transistor to a unipolar carbon nanotube transistor by using gate structure engineering, for example, by providing an asymmetric gate structure with respect to the source and drain electrodes. Using such a process, p-type CNT FETs were produced from am bipolar CNT FETs, and it has been suggested that a gate of the same sort may be used on n-type CNT FETs to cut off the p-type branch of an ambipolar CNT FET with a similar partial gate structure using a relatively deep trench. However, the gate structure requires the formation of a deep trench through the oxide layer and into the gate along the length of the drain electrode, and the ability of such a trench to convert an ambipolar CNT FET to a unipolar CNT FET is a function of the trench width (due to fringing field effects) which makes scale reduction of such devices problematic.

Another method proposed for converting an ambipolar nanotube field effect transistor to a unipolar nanotube field effect transistor proposed using a carrier-trapping material in the carbon nanotube layer itself, such as oxygen molecules adsorbed within the carbon nanotube layer itself. (See, e.g. U.S. Pat. Pub. No. 2007/0246784, the disclosure of which is incorporated herein by reference.) However, such chemical carrier-trapping materials are generally considered too unreliable for use in commercial TFTs and FETs

Accordingly, the need remains for converting ambipolar nanotube TFTs and FETs into unipolar devices, which are more robust and reliable.

### SUMMARY OF THE INVENTION

The present disclosure provides embodiments of carbon nanotube transistors and methods of their manufacture, and more particularly unipolar N- or P-type nanotube transistors.

Many embodiments of the invention are directed to unipolar thin film transistors including:

at least a first dielectric layer;

at least one carbon nanotube active layer, at least a portion of which is in contact with the at least first dielectric layer;

at least one gate electrode such that the at least first dielectric layer is interposed between the one carbon nanotube active layer and the at least one gate electrode;

at least a drain and a source electrode disposed over or under the at least one carbon nanotube active layer; and

at least one n+ or p+ doped layer disposed between the at least one carbon nanotube active layer and the drain and source electrodes, such that the TFT demonstrates unipolar characteristics.

In many other embodiments the doped layer is n+ doped such that the doped layer eliminates a P-type charge carrier injection and transportation in the TFT such that the TFT exhibits an N-type property.

In still many other embodiments the doped layer is p+ doped such that the doped layer eliminates an N-type charge carrier injection and transportation in the TFT such that the TFT exhibits a P-type property.

In yet many other embodiments the doped layer is formed from one of a amorphous, microcrystalline or polycrystalline material selected from the group of: silicon, arsenides and phosphides of gallium, and tellurides and sulfides of cadmium; and wherein the material is doped with a substance selected from the group of phosphorous, arsenic, antimony, bismuth, lithium, beryllium, zinc, chromium, germanium, magnesium, tin, lithium, and sodium, phosphine and diborane.

In still yet many other embodiments the at least first dielectric layer is formed of a material selected from the group consisting of inorganic and organic materials, an oxide, a nitride, and a nitrogen oxide. In some such embodiments the at least first dielectric layer is selected from the group of HfOₓ, SiNx, SiOx, TaOx, AlOx, Y₂O₃, and Si(ON)x.

In still yet many other embodiments the drain and source electrodes are single or multilayer structures formed of one or more of the following materials Cu, Al, Ag, Mo, Cr, Nd, Ni, Mn, Ti, Ta or W.

In still yet many other embodiments the carbon nanotube active layers if formed from one of either double walled carbon nanotubes or single-walled carbon nanotubes. In some such embodiments the single-walled carbon nanotubes are high purity single chirality single-walled carbon nanotubes having an index selected from (6,4), (9,1), (8,3), (6,5), (7,3), (7,5), (10,2), (8,4), (7,6), (9,2), and mixtures thereof.

In still yet many other embodiments the at least one gate is configured as a top-gate.

In still yet many other embodiments the at least one gate is configured as a bottom-gate.

In still yet many other embodiments the thin film transistors may further include a substrate in supportive relationship with the remaining elements of the unipolar thin film transistor.

In still yet many other embodiments the on to off ratio of the transistor is greater than 1E7.

In still yet many other embodiments the transistor mobility is greater than 10 cm²/Vs.

In still yet many other embodiments the active layer may comprise one of a network of carbon nanotubes or aligned and organized sheets of carbon nanotubes.

In still yet many other embodiments the doped layer is formed of an ion implanted carbon nanotube material.

Various embodiments of the invention are directed to methods for manufacturing a unipolar thin film transistor including:

providing a substrate;

patterning a gate electrode and dielectric layer on the substrate;

depositing an active-layer comprised of a thin-film layer of single-walled carbon nanotubes on said dielectric layer;

patterning at least a doped layer, and a drain and a source electrode either below or above the active-layer such that the portion of the active-layer overlapping the channel is exposed, and such that the doped layer is disposed between the drain and the source electrode and the active-layer; and

wherein the doped layer is one of either n+ or p+ doped, such that the TFT demonstrates unipolar characteristics.

Various embodiments of the invention are also directed to methods for manufacturing a top-gated single-walled carbon nanotube thin film transistor including:

providing a substrate;

depositing a dielectric layer on the substrate;

depositing an active-layer comprised of a thin-film layer of single-walled carbon nanotubes on the dielectric layer;

patterning a gate electrode and dielectric layer on the active layer to form a channel;

patterning at least a doped layer, and a drain and a source electrode either below or above the active-layer using a photomask and photolithography process such that the portion of the dielectric overlapping the channel is exposed; and

wherein the doped layer is one of either n+ or p+ doped, such that the TFT demonstrates unipolar characteristics.

In various other embodiments the active-layer is deposited by a technique selected from the group consisting of solution coating, spraying, aerosol jet printing, or transferring.

In still various other embodiments the thin-film active layer comprises one of either a network of carbon nanotubes or aligned and organized sheets of carbon nanotubes.

In yet various other embodiments the doped layer comprises one of either the material of the active layer treated with ion implantation, or a separate doped material. In some such embodiments the doped layer is formed from a separate doped material, and wherein the doped material is deposited using a technique selected from the group of aerosol assisted CVD, direct liquid injection CVD, microwave plasma-assisted CVD, atomic layer CVD, combustion chemical vapor deposition, hot filament CVD, hybrid physical-chemical vapor deposition, rapid thermal CVD, vapor-phase epitaxy, photo-initiated CVD, and atomic layer deposition.

In still yet various other embodiments the doped layer is n+ doped such that the doped layer eliminates a P-type charge carrier injection and transportation in the TFT such that the TFT exhibits an N-type property.

In still yet various other embodiments the doped layer is p+ doped such that the doped layer eliminates an N-type charge carrier injection and transportation in the TFT such that the TFT exhibits a P-type property.

In still yet various other embodiments the doped layer is formed from one of an amorphous, microcrystalline or polycrystalline material selected from the group of: silicon, arsenides and phosphides of gallium, and tellurides and sulfides of cadmium; and wherein the material is doped with a substance selected from the group of phosphorous, arsenic, antimony, bismuth, lithium, beryllium, zinc, chromium, germanium, magnesium, tin, lithium, and sodium, phosphine and diborane.

In still yet various other embodiments the dielectric layer is formed of a material selected from the group consisting of inorganic and organic materials, an oxide, a nitride, and a nitrogen oxide. In some such embodiments the dielectric layer is selected from the group of HfOₓ, SiNx, SiOx, TaOx, AlOx, Y₂Ox, and Si(ON)x.

In still yet various other embodiments the drain and source electrode layers are single or multilayer structures formed of one or more of the following materials Cu, Al, Ag, Mo, Cr, Nd, Ni, Mn, Ti, Ta or W.

In still yet various other embodiments the carbon nanotubes are one of either double walled carbon nanotubes or single-walled carbon nanotubes.

In still yet various other embodiments the single-walled carbon nanotubes are high purity single chirality single-walled carbon nanotubes having an index selected from (6,4), (9,1), (8,3), (6,5), (7,3), (7,5), (10,2), (8,4), (7,6), (9,2), and mixtures thereof.

Additional embodiments and features are set forth in part in the description that follows, and in part will become apparent to those skilled in the art upon examination of the specification or may be learned by the practice of the disclosed subject matter. A further understanding of the nature and advantages of the present disclosure may be realized by reference to the remaining portions of the specification and the drawings, which forms a part of this disclosure.

### BRIEF DESCRIPTION OF THE DRAWINGS

These and other features and advantages of the present apparatus and methods will be better understood by reference to the following detailed description when considered in conjunction with the accompanying data and figures, which are presented as exemplary embodiments of the disclosure and should not be construed as a complete recitation of the scope of the inventive method, wherein:

FIG. 1 provides a schematic diagram of a top gate TFT incorporating SiN in accordance with the prior art.

FIGS. 2A and 2B provides data plots showing the properties of conventional N-type SWCNT TFTs.

FIG. 3 provides a schematic diagram of a top gate TFT incorporating HfO₂ in accordance with the prior art.

FIGS. 4A and 4B provides data plots showing the properties of conventional P-type SWCNT TFTs.

FIGS. 5A and 5B provide schematic diagrams of: (5A) top gate and (5B) bottom gate unipolar SWCNT TFTs in accordance with embodiments.

FIG. 6 provides schematics of a fabrication process for forming top gate unipolar SWCNT TFTs in accordance with embodiments.

FIG. 7 provides a schematic of a top gate unipolar SWCNT TFT in accordance with embodiments.

FIG. 8 provides schematics of a fabrication process for forming top gate SWCNT TFTs in accordance with embodiments.

FIG. 9 provides schematics of a fabrication process for forming bottom gate unipolar SWCNT TFTs in accordance with embodiments.

FIG. 10 provides a schematic of a bottom gate unipolar SWCNT TFT in accordance with embodiments.

FIG. 11 provides schematics of a fabrication process for forming bottom gate SWCNT TFTs in accordance with embodiments.

### DETAILED DESCRIPTION OF THE INVENTION

The embodiments of the inventive methods and apparatus described herein are not intended to be exhaustive or to limit the inventive methods and apparatus to precise forms disclosed. Rather, the embodiments selected for description have been chosen to enable one skilled in the art to practice the invention.

Such words as “first” and “second” or “top” and “bottom” used in the specification and claims are merely used to differentiate different components rather than to represent any order, number, or importance. It is well known in the art that “forming” respective layers indicates sputtering and depositing respective layers of materials, and one or more patterning processes on the materials, such as an etching process, may be needed if necessary. A sequence of steps of any methods provided by embodiments of the present disclosure is not only limited to the one described in the specification, but some of steps can be re-adjusted in sequence or can concurrently happen.

As used herein and in the appended claims, the singular form of a word includes the plural, and vice versa, unless the context clearly dictates otherwise. Thus, the references “a”, “an”, and “the” are generally inclusive of the plurals of the respective terms. Likewise, the terms “include”, “including”, and “having” should all be construed to be inclusive of features, integrals, steps, operations, elements, and/or parts, unless such features, integrals, steps, operations, elements, and/or parts are clearly prohibited from the context, which does not exclude one or more other features, integrals, steps, operations, elements, and/or parts from the present disclosure.

Turning to the drawings, devices, materials and methods for producing and integrating carbon nanotubes (CNT) into TFTs to form unipolar CNT TFTs are provided. Many embodiments are directed to CNT TFTs comprising doped layers between the CNT active layer and the source/drain electrodes capable of providing a carrier-trapping function such that carrier charge injection is suppressed between the electrodes allowing for the unipolar operation of CNT TFTs. Embodiments are also directed to methods and apparatus for forming unipolar N- or P-type SWCNT TFTs. In the following text, carbon nanotubes refer to double-walled carbon nanotubes and single-walled carbon nanotubes, including high purity single chirality SWCNT, such as SWCNTs with indexes of (6,4), (9,1), (8,3), (6,5), (7,3), (7,5), (10,2), (8,4), (7,6), (9,2) and mixtures thereof.

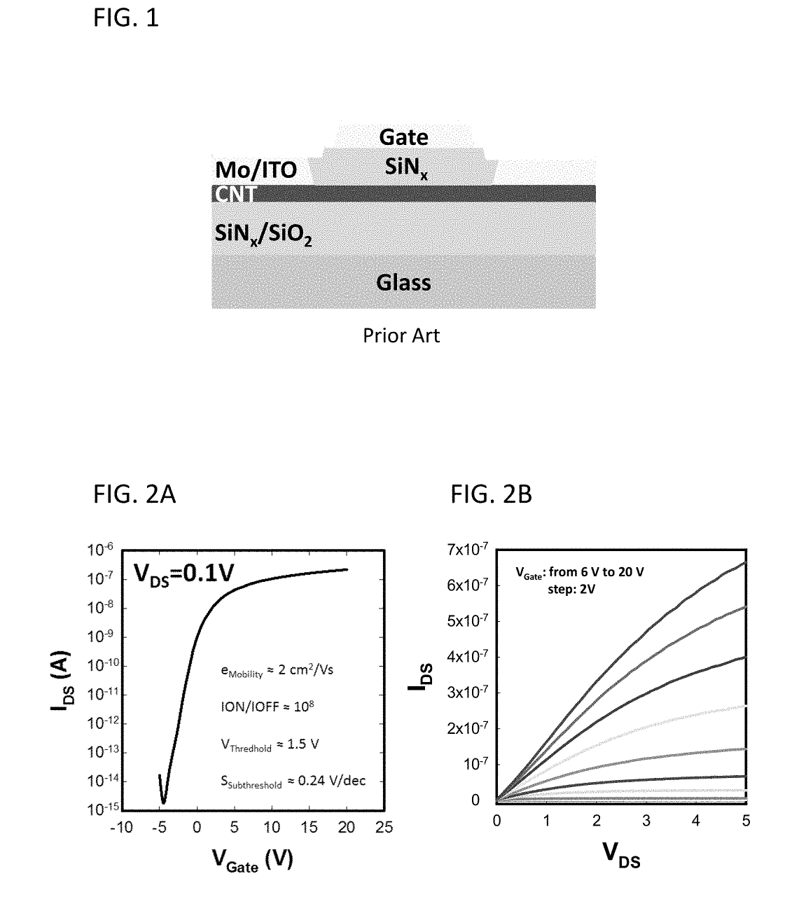

As has been previously described, the use of novel CNT materials and manufacturing combinations, such as highly transparent porous conductive CNT electrodes enable the formation of CNT TFTs that can be incorporated into a number of devices, including TFT backplanes that may overcome the limitations in conventional devices fabricated with amorphous/crystalline/poly silicon, metal oxides and organic materials, and will be suitable for various needs. Exemplary schematics of such devices are shown in FIG. 1, and disclosed, for example, in U.S. patent application Ser. Nos. 14/550,656; 15/244,944; 15/589,896; PCT/US2016/064449; and PCT/US2017/0121161, the disclosures of which are incorporated herein by reference. For example, using such CNT backplanes the higher mobility enables LTPS TFT backplanes to have higher pixel density, lower power consumption, and integration with driving circuits on the glass substrate.

As previously discussed, the use of carbon nanotubes with TFTs and FETs has generally resulted in devices having characteristics that meet or exceed current silicon based transistors which makes carbon nanotube field effect transistors (CNT FETs) interesting for a wide range of electronic applications. However, one challenge in implementing CNTs in devices such as field emission transistors (FETs) and TFTs is that the CNTs ubiquitously exhibit ambipolar properties, limiting the practical applications in display backplanes, CMOS circuits, memories, and radio frequency devices. Specifically, as shown in FIG. 1, a conventional carbon nanotube TFT includes a substrate, a dielectric layer and a gate electrode, which forms an active channel for the device. Source and drain electrodes are also provided above or below these layers, and a carbon nanotube layer is provided between the source and the drain with the carbon nanotube disposed to make electrical contact between them.

In this way, the operational principal of the CNT TFT/FET is generally similar to that of a conventional silicon field effect transistor. However, in these conventional devices the channel between the source and drain is provided by the carbon nanotube instead of by a single crystal of silicon. In these conventional CNT TFT/FETs, the source and drain electrodes are typically comprised of metal(s) although the source and drain electrodes could also be other materials, such as, for example, polysilicon doped to act as a conductor. Although in the conventional CNT TFTs, the carbon nanotube and the source and drain are provided above the gate, it will be understood that the source and drain could be below the gate or that the carbon nanotube could be buried within the device structure. Regardless of the specific construction of the TFT/FET, the CNT film is conventionally in direct contact with the metal electrode.

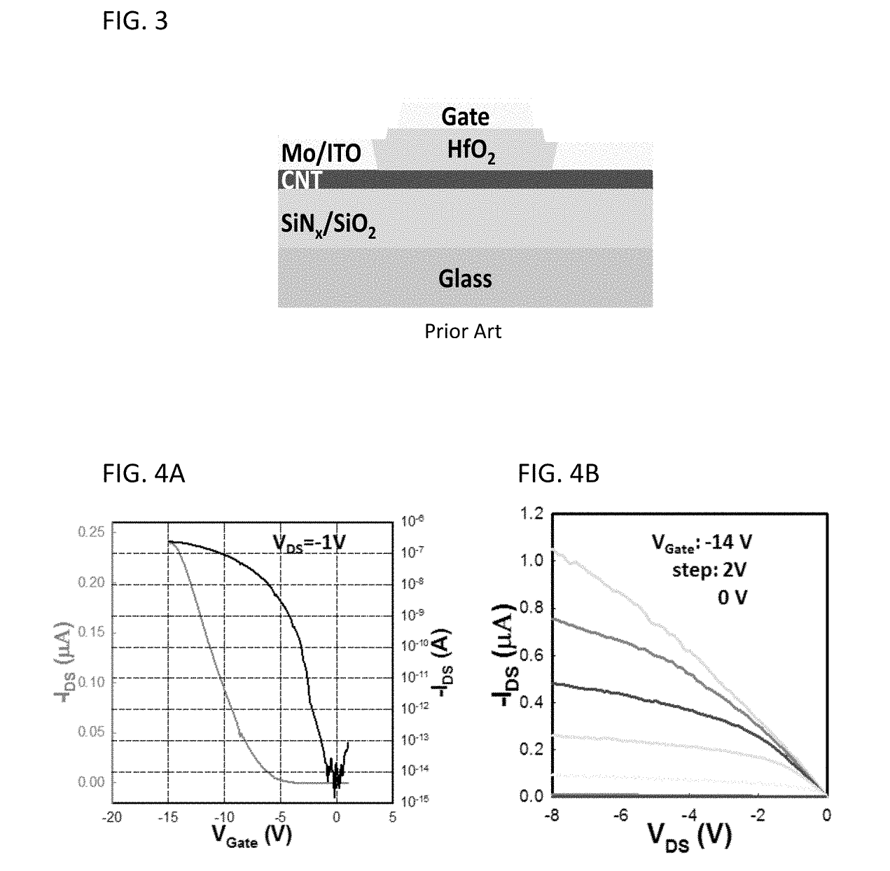

As a result of this architecture, conventional CNT FETs are ambipolar devices. For example, as shown in FIGS. 2A and 2B, CNT TFTs incorporating SiNₓ dielectrics exhibit significant N-characteristics with a P-type tail. By contrast, CNT TFTs incorporating HfO₂ dielectrics (as shown in FIG. 3) exhibit significant P-type properties with an N-type tail, as shown in FIGS. 4A and 4B. Although previous reports have been made of the introduction of n+ or p+ layers in TFTs, as previously discussed, prior disclosures have focused exclusively on changes to the gate architecture or chemical doping of the CNT layers (See, e.g., US Pat Pub No 2015/0102288, the disclosure of which is incorporated herein by reference) or changing the polarity of the electrode. However, these previous attempts to obtain unipolar behavior from such systems are typically too unreliable or difficult to fabricate for commercial application to TFTs. Accordingly, in accordance with current embodiments separate n+ or p+ layers formed by physical doping, such as, for example, in the silicon manufacturing process are provided to affect the unipolar behavior of the SWCNT TFTs.

Embodiments of this disclosure are directed to architectures of unipolar N- or P-type CNT transistors incorporating separate doped n+ or p+ layers between the CNT active layer and the drain/source electrodes that reliably eliminate the unwanted ambipolar properties of conventional CNT TFTs and FETs. Using such unipolar CNT TFT/FET embodiments it has been shown that on to off ratios of 1E7 and TFT mobility exceeding 10 cm²/Vs can be achieved.

### Embodiments of Unipolar SWCNT TFTs

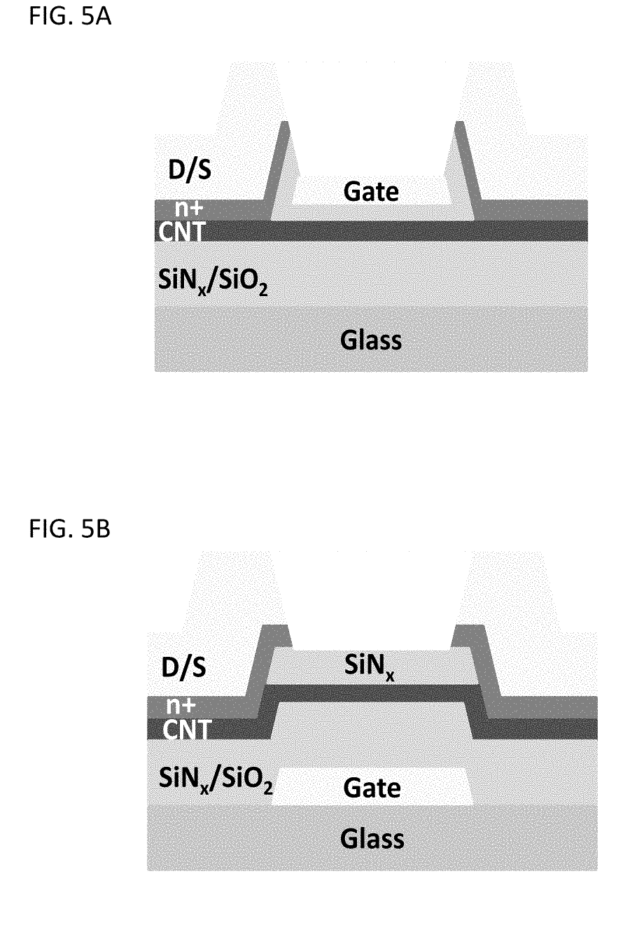

As shown in FIGS. 5A and 5B, unipolar CNT TFTs according to embodiments comprising an n+ or p+ doped layer (as required) disposed between the CNT layer and the metal electrodes are provided. It has been found that incorporating such separate n+ or p+ doped layers between the CNT active layer and the drain/source electrode acts to eliminate positive charge or negative charge injection and collection in the drain electrode, therefore resulting in unipolar N- or P-characteristics in the TFT regardless of its original properties (e.g., ambipolar, etc.). For example, when an n+ doped layer is incorporated between the CNT active layer and the drain/source electrode in a CNT TFT exhibiting N-type properties the n+ layer eliminates the P-type tail, e.g., the positive charge leakage by suppressing hole injection into the active CNT layer, resulting in a unipolar N-type CNT TFT. A similar effect is obtained by incorporating a p+ doped layer between the CNT active layer and the drain/source electrodes in a CNT TFT exhibiting P-type properties (e.g., eliminating the negative charge exhibited by the N-type tail), resulting in a unipolar P-type CNT TFT. In short, the presence of the carrier-trapping doping layer suppresses electron injection from the drain electrode which changes the conventional CNT TFT/FET from an ambipolar device to a unipolar CNT TFT/FET device without reengineering the gate electrode or relying on less reliable chemical doping schemes. It is also been shown that these doped layers also serve to reduce the contact resistance between the CNT and the metal electrode thus improving performance of the TFTs.

Although not to be bound by theory, it is believed that the n+/p+ doped layer provided between the CNT and drain/source electrode acts as a carrier-trapping material. Accordingly, the doped layer trap electrons from the drain electrode. As a result, the band (conduction/valence) moves up with respect to the electrode function. As a result, the energy barrier for electron injection increases which causes the CNT TFT/FET to be unipolar rather than am bipolar.

It will be understood that any suitable amorphous or crystalline n+ or p+ material layer may be incorporated into the TFTs in accordance with embodiments. For example, n+ or p+ doped amorphous Si, or other suitable semiconductors including arsenide and phosphides of gallium, and telluride and sulfides of cadmium may be used. Likewise any suitable plasma and/or n-type/p-type doping materials may be used with such semiconductors, including, for example, phosphorous, arsenic, antimony, bismuth, lithium, beryllium, zinc, chromium, germanium, magnesium, tin, lithium, and sodium, for example. For example, standard amorphous silicon doped with phosphine or diborane may be used in accordance with embodiments, or alternatively microcrystalline Si may be employed using higher deposition power and hydrogen dilution. In addition, these materials may be deposited with any suitable deposition technique including, thermal, physical, plasma, and chemical vapor deposition techniques, as described above. Some suitable techniques include, for example, aerosol assisted CVD, direct liquid injection CVD, microwave plasma-assisted CVD, atomic layer CVD, combustion chemical vapor deposition, hot filament CVD, hybrid physical-chemical vapor deposition, rapid thermal CVD, vapor-phase epitaxy and photo-initiated CVD. Alternatively, atomic layer deposition might be substituted for CVD for the thinner and more precise layers. In still other embodiments the doped layer may comprise a layer of carbon nanotube material that has been ion implanted to form an n+ or p+ doped carbon nanotube material.

As shown in FIGS. 5A and 5B, such n+ and p+ layers may be used to form both unipolar top-gate CNT TFTs (FIG. 5A) and/or unipolar bottom-gate CNT TFTs (FIG. 5B). As shown, regardless of the design, the TFT generally includes a substrate layer (e.g., glass), one or more dielectric layers (e.g., SiN and/or HfO₂), a suitable conductive gate electrode (e.g., metal) formed in either a top (FIG. 5A) or bottom (FIG. 5B) configuration, a CNT active channel layer disposed between the dielectric layers, a set of conductive contacts (e.g., metal/doped Si or the like) formed in conducting arrangement with the CNT layer, and a doping layer (e.g., either n+ or p+) disposed between the CNT layer and the contacts. In many such embodiments, incorporating such n+ or p+ doped layers between the CNT active layer and the drain/source electrode acts to eliminate positive charge or negative charge carrier injection and transfer to or collection in the drain electrode, therefore resulting in unipolar N- or P-characteristics in the TFT regardless of its original properties (e.g., ambipolar, etc.)

Although specific exemplary materials are described above, it should be understood that these are not meant to be limiting and any suitable alternative may be used. For example, although the substrate in the figures is listed as being glass, it should be understood that any material having sufficient optical transmission (e.g., in many embodiments, on the order of 80% or greater), and capable of resisting degradation at industrial standard processing temperatures (e.g., 100° C. and higher) may be used. Exemplary substrate material may include glass, polyethylene terephthalate (PET), polyethesulphone (PES), palyarylate (PAR), and polycarbonate (PA), among others. Similarly, the gate electrode and contacts may be made of any conductor or semiconductor. Conductors could be any suitable metal such as Cu, Al, Ag, Mo, Cr, Nd, Ni, Mn, Ti, Ta or W, or the alloy of two or more of these metals. The gate metal layer or contact may also be in a single layer structure or a multi-layer structure, and the multi-layer structure may be of, for example Cu\Mo, Ti\Cu\Ti, Mo\AI\Mo or etc. Alternatively, the contacts may be formed of a suitable semiconductor, such as doped Si, or the like. The thickness of the gate electrode and contacts may also be of any suitable size, such as from 10 nm to more than 100 μm.

In many embodiments the dielectric layer may be made of inorganic and organic materials, an oxide, a nitride, or a nitrogen oxide, such as, for example, SiNx, SiOx, TaOx, AlOx, HfOₓ, Y₂O₃, or Si(ON)x. Moreover, the dielectric layer may be in a single layer structure, a dual layer structure or a multi-layer structure. The thicknesses of such structures may be take any size suitable to provide the dielectric function. In addition, the dielectric layer may be formed atop the substrate and gate electrode by any suitable thin filming process, including, for example, magnetron sputtering, thermal evaporation, CVD (remote plasma, photo catalytic, etc.), PECVD, spin coating, liquid phase growth, etc. Finally, any suitable carbon nanotubes can be used in the active TFT channel layer accordance with embodiments. In many embodiments double-walled or single-walled carbon nanotubes, including high purity single chirality SWCNT (e.g., >95% purity) having a wide variety of indexes may be used. In many embodiments, high purity single chirality SWCNTs and mixtures incorporating SWCNTs with indexes of (6,4), (9,1), (8,3), (6,5), (7,3), (7,5), (10,2), (8,4), (7,6), (9,2) may be used. In addition, these carbon nanotube active layers may be formed of networks of carbon nanotubes or aligned and organized sheets of carbon nanotubes.

### Embodiments of Methods of Forming Unipolar CNT TFTs

Embodiments are also directed to methods and processes for fabricating unipolar TFTs incorporating semiconducting single-walled carbon nanotubes to replace amorphous silicon layer in industrial TFT backplanes. In particular, as shown in FIGS. 55A and 5B, in accordance with embodiments top gated unipolar CNT TFTs (e.g., FIG. 5A), and bottom gated CNT TFTs (e.g., FIG. 5B) may be implemented, among others. Although the methods and processes below will be described with reference to specific top and bottom gate unipolar TFT backplane configurations, it will be understood that any TFT backplane design into which a CNT layer may be substituted for the silicon layer, and into which the suitable n+ or p+ layer may also be implemented, may be formed as a unipolar embodiment, including, for example, coplanar TFTs, short-channeled TFTs, staggered TFTs, planar TFTs and self-aligned TFTs.

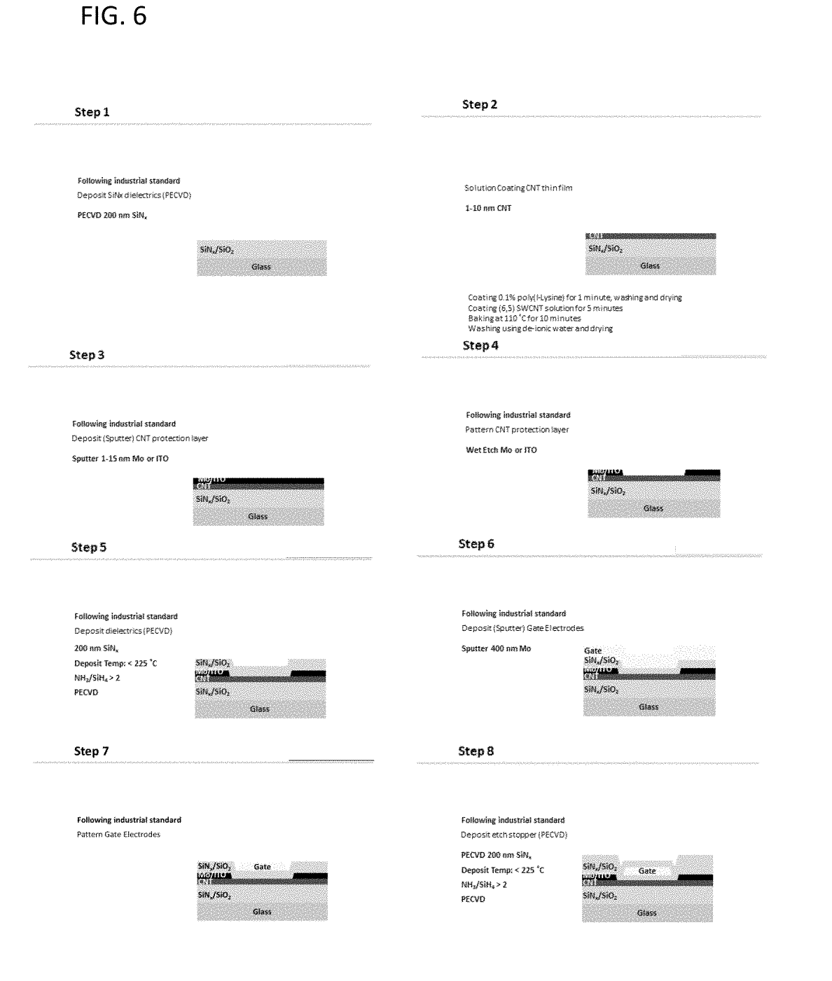

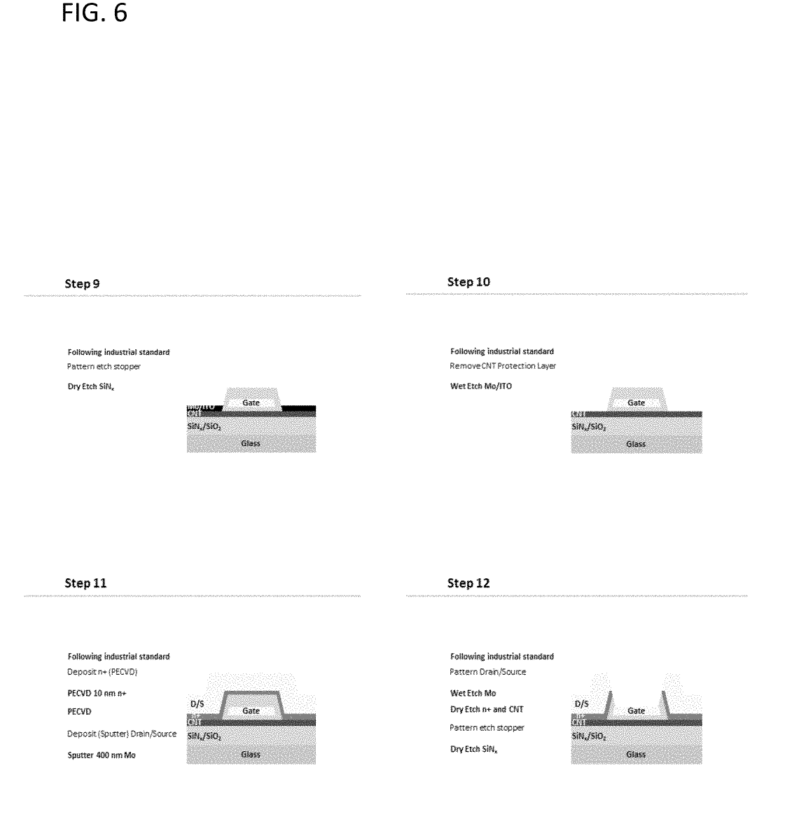

Although many processes may be used to form such unipolar CNF TFTs, including specifically top gated etch-stop CNT TFTs, many such embodiments use a process as summarized in FIG. 6 and described below. As shown, the method requires a number of process steps into which the dope layers and CNT layers are integrated. These steps include:

STEP 1: The provision of a suitable substrate and the formation atop the substrate of a suitable dielectric.

STEP 2: The deposition of a CNT thin film layer atop the dielectric layer.

STEP 3: The deposition of a CNT protection layer atop the CNT thin film layer.

STEP 4: The patterning of the CNT protection layer to expose a portion of the CNT layer corresponding to the ultimate location of the gate electrode, leaving at least the edges with the CNT thin film covered by the CNT protection layer.

STEP 5: The deposition of an etch stopper dielectric layer atop the exposed portion of the CNT thin film and remaining CNT protection layer.

STEP 6: The deposition of the gate electrode layer atop the dielectric layer.

STEP 7: The patterning and etching of the gate electrode.

STEP 8: The deposition of an etch stopper dielectric layer atop the gate electrode.

STEP 9: The patterning and etching of the etch stopper dielectric layer to expose the CNT protection layer on the edges of the TFT leaving the second dielectric layer selectively atop the gate electrode.

STEP 10: The removing of the remaining CNT protection layer to expose the CNT thin film on the edges of the gate electrode channel.

STEP 11: The deposition of a doped layer (n+ or p+ as appropriate) atop the CNT thin film and the etch stop dielectric layer, and the deposition of the drain/source electrode layer atop the n+ doped layer.

STEP 12: The patterning and etching of the drain/source electrodes and n+ or p+ layer.

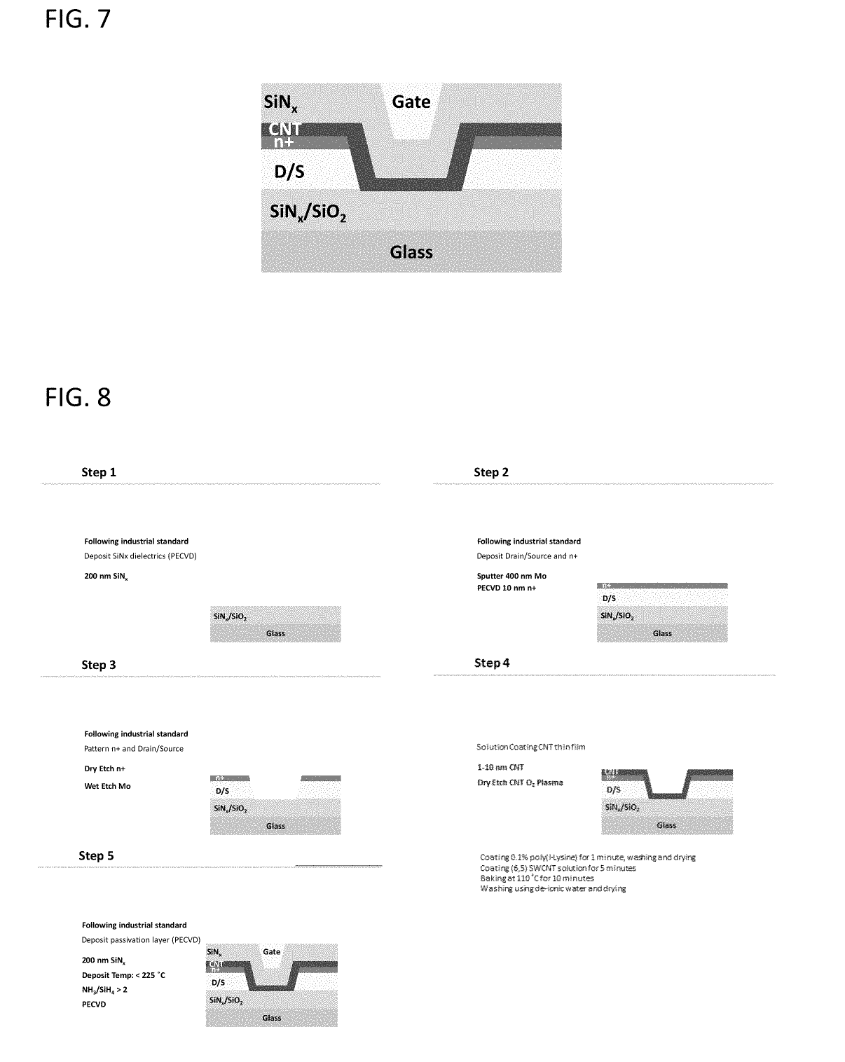

The processing of such a CNT TFT requires a few additional deposition steps, however it can be advantageous in some respects because the intrinsic layer can remain thin (e.g., less than ˜200 nm). Despite the above description, it will be understood that the CNT layers can also be combined with other structures and techniques, including, for example back-channel-etched (BCE) TFTs, etc. The process may also be simplified, such as by implementing a pre-patterned gate electrode, as shown, for example, in FIGS. 7 and 8. Although the overall structure of the unipolar TFT is similar to that provided in FIG. 5A, as shown in FIG. 8, such a process is substantially simplified, incorporating the following steps:

STEP 1: The provision of a suitable substrate and the formation atop the substrate of a suitable dielectric.

STEP 2: The deposition of the drain/source electrode layer, and the deposition of a doped layer (n+ or p+ as appropriate) atop the electrode layer.

STEP 3: The patterning and etching of the drain/source electrodes and the doped layer.

STEP 4: The deposition of a CNT thin film layer atop the doped layer and exposed dielectric layer.

STEP 5: The deposition of an etch stopper dielectric layer atop the CNT thin film and the deposition of the gate electrode layer atop the dielectric layer.

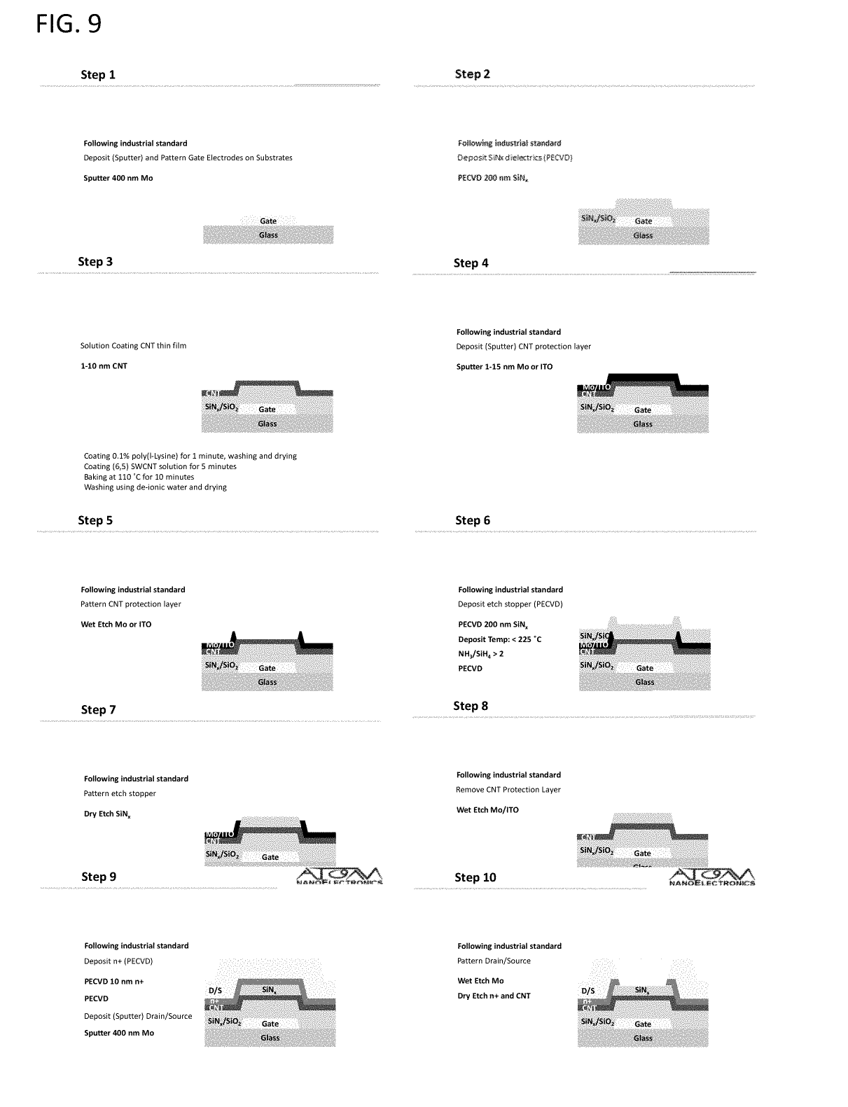

Although the above-discussion has focused on methods of forming unipolar top-gated CNT TFTs, it will be understood that embodiments are also directed to methods of forming unipolar bottom-gated CNT TFTs, as shown, for example, in FIG. 9. These steps may include:

STEP 1: The provision of a substrate and the formation atop the substrate of a patterned gate electrode.

STEP 2: The deposition of a gate electrode dielectric atop the gate electrode layer.

STEP 3: The deposition of a CNT thin film layer atop the gate dielectric.

STEP 4: The deposition of a passivation layer atop the CNT thin film layer.

STEP 5: The removing of the CNT protection layer over the gate electrode channel.

STEP 6: The deposition of an etch stopper dielectric layer atop the exposed portion of the CNT thin film and remaining CNT protection layer.

STEP 7: The patterning and etching of the etch stopper dielectric layer to expose the CNT protection layer on the edges of the TFT leaving the second dielectric layer selectively atop the gate electrode.

STEP 8: The removing of the remaining CNT protection layer to expose the CNT thin film on the edges of the gate electrode channel.

STEP 9: The deposition of a doped layer (n+ or p+ as appropriate) atop the CNT thin film and the etch stop dielectric layer, and the deposition of the drain/source electrode layer atop the n+ doped layer.

STEP 10: The patterning and etching of the drain/source electrodes and a doped n+ or p+ layer.

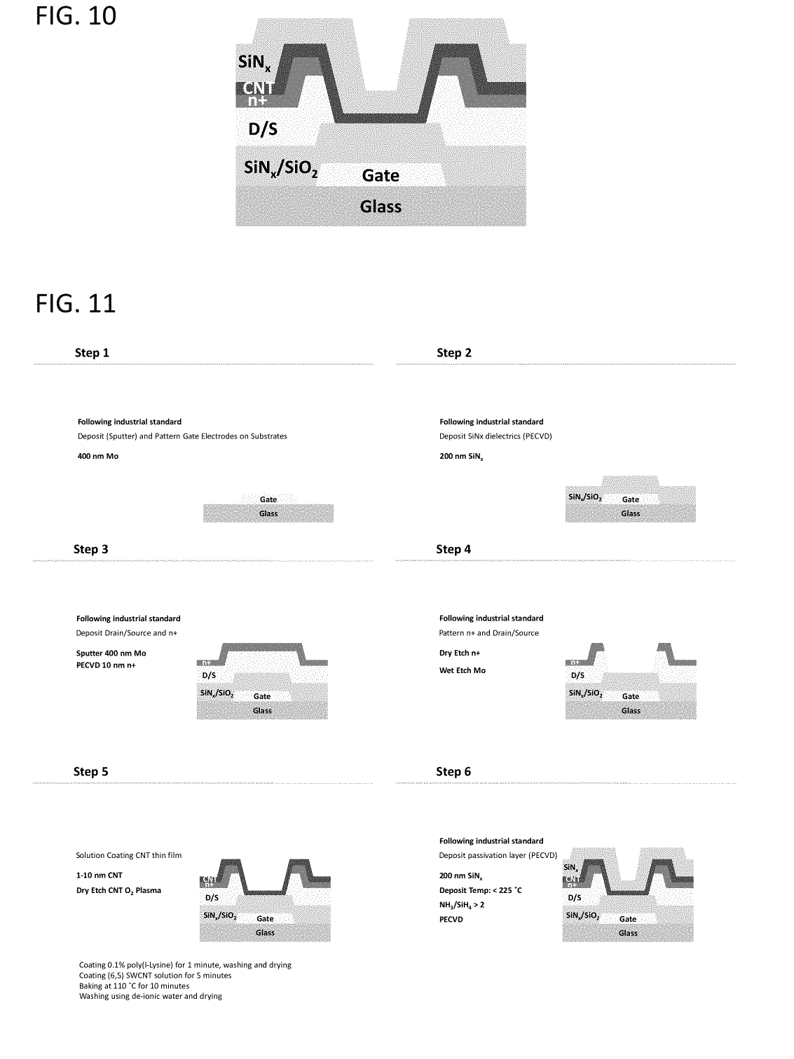

As with the process for forming top-gated unipolar CNT TFTs the process for forming bottom-gated CNT TFTs may also be simplified, as shown, for example, in FIGS. 10 and 11. Although the overall structure of the unipolar TFT is similar to that provided in FIG. 5B, as shown in FIG. 11, such a process is substantially simplified, incorporating the following steps:

STEP 1: The provision of a suitable substrate and the formation atop the substrate of a suitable gate electrode.

STEP 2: The deposition of a suitable gate dielectric atop the gate electrode.

STEP 3: The deposition of the drain/source electrode layer, and the deposition of a doped layer (n+ or p+ as appropriate) atop the electrode layer.

STEP 3: The patterning and etching of the drain/source electrodes and the doped layer.

STEP 4: The deposition of a CNT thin film layer atop the doped layer and exposed dielectric layer.

STEP 5: The deposition of an etch stopper dielectric layer atop the CNT thin film.

Although the above methods are described in FIGS. 6 to 11 with respect to specific deposition techniques, it should be understood that many alternative embodiments and techniques may be used in association with the unipolar CNT TFTs in accordance with embodiments.

For example, in some such embodiments, as shown in the figures, a substrate is provided onto which the remaining structures of the TFT are disposed. Although the substrate in the figures is listed as being glass, as previously discussed it should be understood that any material described herein and having sufficient optical transmission (e.g., in many embodiments, on the order of 80% or greater), and capable of resisting degradation at industrial standard processing temperatures (e.g., 100° C. and higher) may be used. Similarly, the gate electrode may be made of any suitable conductive materials such as a metal or doped Si material, for example. Moreover, although the gate electrode is shown as a single layer, it should be understood that it may be a multi-layer structure, as described above.

Likewise, although the process for depositing the gate electrode is often listed as comprising the steps of sputtering and patterning, it should be understood that many suitable and standard industrial processes may be use to pattern and deposit gate electrodes. For example, sputtering (or physical vapor deposition) may include one or a combination of electronic, potential, etching and chemical sputtering, among others. Deposition techniques may alternatively include, for example, chemical (CVD), plasma-enhanced vapor deposition (PECVD), and/or thermal evaporation, etc.

Similarly, the patterning of the gate electrode may incorporate any suitable photoengraving process, such as wet or dry etching, including the utilization of any suitable photoresist and etching chemicals. In many such embodiments the gate electrode may be coated with a layer of a suitable photoresist, the photoresist may then be exposed and developed by the mask plate to respectively form a photoresist unreserved area and a photoresist reserved area. In many such embodiments the photoresist reserved area corresponds to an area where the gate electrode is to be arranged, and the photoresist unreserved area corresponds to other areas. In such embodiments the gate electrode layer of the photoresist unreserved area may be completely etched off by the etching process, and the remaining photoresist removed, so that the gate electrode is formed.

Turning to the deposition of the dielectric layer, again, although a PECVD process and a SiN or HfO₂ dielectric material is specified in the figures, it should be understood that any suitable dielectric material and deposition process may be incorporated with methods. For example, in many embodiments the dielectric layer may be made of inorganic and organic materials, an oxide, a nitride, or a nitrogen oxide, such as, for example, HfOₓ, SiNx, SiOx, TaOx, AlOx, Y₂O₃, or Si(ON)x. Moreover, the dielectric layer may be in a single layer structure, a dual layer structure or a multi-layer structure. The thicknesses of such structures may be take any size suitable to provide the dielectric function. In addition, the dielectric layer may be formed by any suitable the filming process, including, for example, magnetron sputtering, thermal evaporation, CVD (remote plasma, photo catalytic, etc.), PECVD, spin coating, liquid phase growth, etc. In various such embodiments, the unipolar CNT TFTs may incorporate SiNx/SiO2 layers deposited via PECVD at thicknesses of around 200 nm. Finally, if necessary a variety of feedstock gas molecules may be made in association with such dielectric materials, including SiHx, NHx, N₂, and hydrogen free radical and ions. Similar techniques and materials may be used for the other passivation layers, including those etch-stop. In these steps the deposit temperatures and thicknesses of the passivation materials may be chosen as required.

Regardless of whether the unipolar TFT is a top or bottom-gated TFT, all TFTs also require the deposition of a doped layer and drain/source layers, as shown in FIGS. 3i & 3j, and 4c. Although the figures show that sputter deposition of an approximately 400 nm Mo drain/source layer, and PECVD deposition of a thin (˜10 nm) n+ doped layer, it should be understood that any suitable combination of deposition techniques and materials may be utilized. For example, the drain/source electrode layer may be made of any suitable metal such as Cu, Al, Ag, Mo, Cr, Nd, Ni, Mn, Ti, Ta or W, or the alloy of two or more of these metals. The drain/source electrode may be in a single layer structure or a multi-layer structure, and the multi-layer structure may be of, for example Cu\Mo, Ti\Cu\Ti, Mo\AI\Mo or etc. The thickness of the drain/source electrode layer may be similarly be of any suitable size, such as from 10 nm to more than 100 μm, and in some embodiments around 400 nm, as shown in the figures. Likewise, although the process for depositing the drain/source is listed as comprising the steps of sputtering and patterning, it should be understood that many suitable and standard industrial processes may be use to pattern and deposit gate electrodes atop the substrate. For example, sputtering (or physical vapor deposition) may include one or a combination of electronic, potential, etching and chemical sputtering, among others. Deposition techniques may alternatively include, for example, chemical (CVD), plasma-enhanced vapor deposition (PECVD), and/or thermal evaporation, etc.

Similarly, as described above, any suitable doping material may be incorporated into the TFTs in accordance with embodiments, include, for example, n+ or p+ doped amorphous or microcrystalline Si, or other suitable semiconductors including arsenide and phosphides of gallium, and telluride and sulfides of cadmium. Likewise and suitable plasma and/or n-type or p-type doping materials may be used with such semiconductors, including, for example, phosphorous, arsenic, antimony, bismuth, lithium, beryllium, zinc, chromium, germanium, magnesium, tin, lithium, and sodium, for example. And, these materials may be deposited with any suitable deposition technique including, thermal, physical, plasma, and chemical vapor deposition techniques, as described above. Some suitable techniques include, for example, aerosol assisted CVD, direct liquid injection CVD, microwave plasma-assisted CVD, atomic layer CVD, combustion chemical vapor deposition, hot filament CVD, hybrid physical-chemical vapor deposition, rapid thermal CVD, vapor-phase epitaxy and photo-initiated CVD. Alternatively, atomic layer deposition might be substituted for CVD for the thinner and more precise layers.

A number of steps in such processes also require the patterning and etching of materials. In such processes any suitable patterning and etching technique may be incorporated with embodiments. In particular, many of the steps incorporate a patterning process by which a passivation layer is deposited and a pattern is formed through the passivation layer. Specifically, in many embodiments the passivation layer may be coated with a layer of any suitable photoresist. In such embodiments the photoresist may be exposed and developed by a mask plate to respectively form a photoresist unreserved area and a photoresist reserved area. For example, the photoresist of the unreserved area may correspond in various embodiments to an area where the via hole of the passivation layer is arranged.

Any suitable optical photolithographic technique may be used, including for example, immersion lithography, dual-tone resist and multiple patterning electron beam lithography, X-ray lithography, extreme ultraviolet lithography, ion projection lithography, extreme ultraviolet lithography, nanoimprint lithography, dip-pen nanolithography, chemical lithography, soft lithography and magneto lithography, among others.

Regardless of the specific techniques and light source used, such lithographic techniques generally incorporate several steps. In many embodiments, the layer to be patterned is first coated with a photoresist, such as by spin coating. In such techniques, a viscous, liquid solution of photoresist is dispensed onto the wafer, and the wafer is spun rapidly to produce a uniformly thick layer. The spin coating typically runs at 1200 to 4800 rpm for 30 to 60 seconds, and produces a layer between 0.5 and 2.5 micrometers thick. The spin coating process results in a uniform thin layer, usually with uniformity of within 5 to 10 nanometers, or more. In various embodiments, the photo resist-coated material may then be prebaked to drive off excess photoresist solvent, typically at 90 to 100° C. for 30 to 60 seconds on a hotplate. After the non-masked portions of the layer are etched, either by a liquid (“wet”) or plasma (“dry”) chemical agent to remove the uppermost layer of the substrate in the areas that are not protected by photoresist. After a photoresist is no longer needed, it is then removed from the substrate. This photoresist may be removed chemically or by a plasma or by heating.

Although specific deposition and patterning methods are disclosed, as well as specific materials for substrates, electrodes, dielectrics, passivation layers, etc., and specific conditions, including, thicknesses, temperatures etc., it will be understood that any of these parameters may be adjusted as necessary for the specific unipolar TFT configuration and operational parameters without fundamentally altering the principles of embodiments that incorporate the CNTs disclosed herein.

Turning to embodiments of methods for depositing the CNT layers in the TFTs, in many embodiments various techniques may be used, including various depositions and spraying methods.

In many embodiments, single-walled carbon nanotube thin films are solution coated using a spraying technique, such as air, aerosol or ultrasonic spraying in association with a moving station manufacturing line. For example, a carbon nanotube solution may be sprayed (e.g., by aerosol or air spray coating) onto the substrates of a suitable size (e.g., 4″-100″) while heating them at a desirable processing temperature (e.g., from 60-200° C., or any temperature that is allows by the underlying materials and the CNT materials themselves). Alternatively they may be transferred from filtered or self-assembled films.

In other embodiments, ultrasonic spray coating may be used. In such embodiments, a stream of compressed air is passed through an aspirator, which creates a local reduction in air pressure that allows the carbon nanotube solution to be pulled out from a container at normal atmospheric pressure. During processing, the ultrasonicating nozzle atomizes the carbon nanotube solution into very tiny droplets of, for example, anywhere from a few pm to around 1000 μm in diameter. The tiny droplets are then deposited onto substrates at a suitable processing temperature (e.g., up to 400° C.), such that the droplets are immediately dried to mitigate the O-ring aggregations. In various embodiments, a temperature of 100° C. may be used. Although any suitable air pressure may be used (dependent on the viscosity of the material, in many embodiments the compressed air pressure can be ranged from 20 psi (1.38 bar) to 100 psi (6.8 bar) dependent upon the solution viscosity and the size of aspirator required for the deposition.

In embodiments incorporating aerosol spray coating the carbon nanotube solution may be atomized using high pressure gas (e.g., 200-1000 standard cubic centimeter per minute (sccm)), or ultra-sonication (e.g., 20 V-48 V, 10-100 Watts) to produce 1-5 micron aerosols that are brought to spray head by carrier gas (e.g., 10-30 sccm). It should be understood that these processing parameters are only exemplary and that other deposition properties may be used dependent on the type of material, the nature of aerosols desired and the thickness of the coatings to be formed.

In many embodiments, thus formed carbon nanotube thin films are treated by de-ionized water or acetic acid gas generated by airbrush spray or aerosol spray and then washed with isopropanol to achieve clear carbon nanotube surfaces.

In order to reduce the subthreshold current leakage, other embodiments may employ at least one additional photomask to pattern the active carbon nanotube thin layer using photolithography. In such embodiments, the CNT layer outside of the transistor channels may be removed by a suitable etching technique, such as, for example, O₂ plasma or wet etching. In various such embodiments, the clear uniform carbon nanotube thin film may be photoresist (PR) coated and photo exposed, and then solution developed. On these developed areas, the carbon nanotube thin film is etched using, for example, O₂ plasma or a wet chemical etching, such as a buffered HF solution. The undeveloped PR is then stripped off to leave a patterned carbon nanotube thin film.

In still other embodiments, to reduce the use of an extra photomask to pattern active carbon nanotubes and to reduce the consumption of the carbon nanotube solution, the SWCNT thin films may be printed atop the substrate. In many such embodiments, an aerosol jet printer may be used to print the active carbon nanotube thin film using small nozzle size (e.g., <100 μm). An aerosol jet printer can deposit <10 μm linewidth with <2 μm registration accuracy. To do so, the aerosol jet printer prints carbon nanotubes on patterned drain/source marks.

To further take advantage of low-cost, low environmental impact and large area fabrication due to the small number of process steps, limited amount of material and high through-put, embodiments propose to aerosol jet printing methods described above (including its high precision: registration accuracy of 1-2 μm) with a roll-to-roll system with high speed process. With such a roll-to-roll aerosol jet printer, SWCNT ink can be printed in a rapid way for mass production in a-Si TFT backplane manufacturing line. In addition, fully printed SWCNT TFT backplanes can be fabricated massively using roll-to-roll system. On a moving station, such multiple aerosol jet printer heads can print a large number of carbon nanotube patterns.

Regardless of the specific technique used, in embodiments, carbon nanotube thin films formed in accordance with such spray coating processes may be used to replace amorphous silicon in 4-photomask photolithography processes to pattern drain/source electrodes, dielectrics, top-gated electrodes, and pixel electrodes following industry manufacturing standard methods, as described above with respect to FIGS. 6 and 11, to form unipolar CNT TFTs. Moreover, methods according to many such embodiments allow for the complete device to be made at low temperature on a plastic having a T_{g}<200 400° C.

It should be understood that the above steps are provided as exemplary; other steps or the order of the steps may be altered (as will be understood) without departing from the scope of the disclosure. The person skilled in the art will recognize that additional embodiments according to the invention are contemplated as being within the scope of the foregoing generic disclosure, and no disclaimer is in any way intended by the foregoing, non-limiting examples.

### DOCTRINE OF EQUIVALENTS

Having described several embodiments, it will be recognized by those skilled in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Those skilled in the art will appreciate that the foregoing examples and descriptions of various preferred embodiments of the present invention are merely illustrative of the invention as a whole, and that variations in the components or steps of the present invention may be made within the spirit and scope of the invention. Accordingly, the present invention is not limited to the specific embodiments described herein, but, rather, is defined by the scope of the appended claims.

What is claimed is:

1. A unipolar thin film transistor comprising
at least a first dielectric layer;
at least one carbon nanotube active layer, at least a portion of which is in contact with the at least first dielectric layer;
at least one gate electrode such that the at least first dielectric layer is interposed between the one carbon nanotube active layer and the at least one gate electrode;
at least a drain and a source electrode disposed over or under the at least one carbon nanotube active layer
at least one n+ or p+ doped layer disposed between the at least one carbon nanotube active layer and the drain and source electrodes, such that the TFT demonstrates unipolar characteristics.

2. The unipolar thin film transistor of claim 1, wherein the doped layer is n+ doped such that the doped layer eliminates a P-type charge carrier injection and transportation in the TFT such that the TFT exhibits an N-type property.

3. The unipolar thin film transistor of claim 1, wherein the doped layer is p+ doped such that the doped layer eliminates an N-type charge carrier injection and transportation in the TFT such that the TFT exhibits a P-type property.

4. The unipolar thin film transistor of claim 1, wherein the doped layer is formed from one of a amorphous, microcrystalline or polycrystalline material selected from the group of: silicon, arsenides and phosphides of gallium, and tellurides and sulfides of cadmium;
and wherein the material is doped with a substance selected from the group of phosphorous, arsenic, antimony, bismuth, lithium, beryllium, zinc, chromium, germanium, magnesium, tin, lithium, and sodium, phosphine and diborane.

5. The unipolar thin film transistor of claim 1, wherein the at least first dielectric layer is formed of a material selected from the group consisting of inorganic and organic materials, an oxide, a nitride, and a nitrogen oxide.

6. The unipolar thin film transistor of claim 5, wherein the at least first dielectric layer is selected from the group of HfOₓ, SiNx, SiOx, TaOx, AlOx, Y₂O₃, and Si(ON)x.

7. The unipolar thin film transistor of claim 1, wherein the drain and source electrodes are single or multilayer structures formed of one or more of the following materials Cu, Al, Ag, Mo, Cr, Nd, Ni, Mn, Ti, Ta or W.

8. The unipolar thin film transistor of claim 1, wherein the carbon nanotube active layers if formed from one of either double walled carbon nanotubes or single-walled carbon nanotubes.

9. The unipolar thin film transistor of claim 8, wherein the single-walled carbon nanotubes are high purity single chirality single-walled carbon nanotubes having an index selected from (6,4), (9,1), (8,3), (6,5), (7,3), (7,5), (10,2), (8,4), (7,6), (9,2), and mixtures thereof.

10. The unipolar thin film transistor of claim 1, wherein the at least one gate is configured as a top-gate.

11. The unipolar thin film transistor of claim 1, the at least one gate is configured as a bottom-gate.

12. The unipolar thin film transistor of claim 1, further comprising a substrate in supportive relationship with the remaining elements of the unipolar thin film transistor.

13. The unipolar thin film transistor of claim 1, wherein the on to off ratio of the transistor is greater than 1E7.

14. The unipolar thin film transistor of claim 1, wherein the transistor mobility is greater than 10 cm²/Vs.

15. The unipolar thin film transistor of claim 1, wherein the active layer may comprise one of a network of carbon nanotubes or aligned and organized sheets of carbon nanotubes.

16. The unipolar thin film transistor of claim 1, wherein the doped layer is formed of an ion implanted carbon nanotube material.

17. A method for manufacturing a unipolar thin film transistor comprising one of either a bottom-gate or a top-gate process:
wherein the bottom-gate process comprises:
providing a substrate,
patterning a gate electrode and dielectric layer on the substrate,
depositing an active-layer comprised of a thin-film layer of single-walled carbon nanotubes on said dielectric layer,
patterning at least a doped layer, and a drain and a source electrode either below or above the active-layer such that the portion of the active-layer overlapping the channel is exposed, and such that the doped layer is disposed between the drain and the source electrode and the active-layer, and
wherein the doped layer is one of either n+ or p+ doped, such that the TFT demonstrates unipolar characteristics; and
wherein the top-gate process comprises:
providing a substrate;
depositing a dielectric layer on the substrate;
depositing an active-layer comprised of a thin-film layer of single-walled carbon nanotubes on the dielectric layer;
patterning a gate electrode and dielectric layer on the active layer to form a channel;
patterning at least a doped layer, and a drain and a source electrode either below or above the active-layer using a photomask and photolithography process such that the portion of the dielectric overlapping the channel is exposed; and
wherein the doped layer is one of either n+ or p+ doped, such that the TFT demonstrates unipolar characteristics.

18. The method of one of either claims 17, wherein the active-layer is deposited by a technique selected from the group consisting of solution coating, spraying, aerosol jet printing, or transferring.

19. The method of one of either claims 17, wherein the thin-film active layer comprises one of either a network of carbon nanotubes or aligned and organized sheets of carbon nanotubes.

20. The method of one of either claims 17, wherein the doped layer comprises one of either the material of the active layer treated with ion implantation, or a separate doped material.

21. The method of claim 20, wherein the doped layer is formed from a separate doped material, and wherein the doped material is deposited using a technique selected from the group of aerosol assisted CVD, direct liquid injection CVD, microwave plasma-assisted CVD, atomic layer CVD, combustion chemical vapor deposition, hot filament CVD, hybrid physical-chemical vapor deposition, rapid thermal CVD, vapor-phase epitaxy, photo-initiated CVD, and atomic layer deposition.

22. The method of one of either claims 17, wherein the doped layer is n+ doped such that the doped layer eliminates a P-type charge carrier injection and transportation in the TFT such that the TFT exhibits an N-type property.

23. The method of one of either claims 17, wherein the doped layer is p+ doped such that the doped layer eliminates an N-type charge carrier injection and transportation in the TFT such that the TFT exhibits a P-type property.

24. The method of one of either claims 17, wherein the doped layer is formed from one of an amorphous, microcrystalline or polycrystalline material selected from the group of: silicon, arsenides and phosphides of gallium, and tellurides and sulfides of cadmium; and wherein the material is doped with a substance selected from the group of phosphorous, arsenic, antimony, bismuth, lithium, beryllium, zinc, chromium, germanium, magnesium, tin, lithium, and sodium, phosphine and diborane.

25. The method of one of either claims 17, wherein the dielectric layer is formed of a material selected from the group consisting of inorganic and organic materials, an oxide, a nitride, and a nitrogen oxide.

26. The method of claim 25, wherein the dielectric layer is selected from the group of HfOₓ, SiNx, SiOx, TaOx, AlOx, Y₂Oₓ, and Si(ON)x.

27. The method of one of either claims 17, wherein the drain and source electrode layers are single or multilayer structures formed of one or more of the following materials Cu, Al, Ag, Mo, Cr, Nd, Ni, Mn, Ti, Ta or W.

28. The method of one of either claims 17, wherein the carbon nanotubes are one of either double walled carbon nanotubes or single-walled carbon nanotubes.

29. The method of claim 28, wherein the single-walled carbon nanotubes are high purity single chirality single-walled carbon nanotubes having an index selected from (6,4), (9,1), (8,3), (6,5), (7,3), (7,5), (10,2), (8,4), (7,6), (9,2), and mixtures thereof.
